(19) United States
(12) Patent Application Publication
(10) Pub. No.: US 2008/0315862 A1
(43) Pub. Date: Dec. 25, 2008

(54) SMART PARALLEL CONTROLLER FOR SEMICONDUCTOR EXPERIMENTS

(75) Inventor: Shay-Tsion Daniel, Rehovot (IL)

Correspondence Address: Beyer Law Group LLP, P.O. BOX 1687, Cupertino, CA, 95015-1687, US

(73) Assignee: QUALITAU, INC., Sunnyvale, CA (US)

(21) Appl. No.: 11/766,706

(22) Filed: Jun. 21, 2007

(51) Int. Cl. G01R 31/28

(52) U.S. Cl. 324/73.1

(57) ABSTRACT

An instrument is configured to coordinate execution of a plurality of experiments employing a plurality of source measurement units (SMU's) to characterize a plurality of devices under test (DUT's). Each experiment controller, of a plurality of experiment controllers, is configured to manage one of the plurality of experiments by, at least in part, controlling the SMU's allocated to that experiment. A main controller is configured to interoperate with a host to manage the experiment controllers. For example, the instrument may be configured to provide experiment parameters to the SMU's prior to execution of the experiments. In one aspect, the main controller is configured to receive experiment parameters from a host controller external to the instrument. At least in part based on the received experiment parameters, the main controller configure which experiment controllers are to manage which experiment. The main controller is also configured to cause each experiment controller to provide appropriate ones of the received experiment parameters to the SMU's allocated to the experiment which that experiment controller is configured to manage.

### BACKGROUND

Semiconductor device parametric characterization is conventionally performed using an instrument (hereinafter “instrument”) that enables running of experiments over Devices Under Test (hereinafter “DUT”) and determining the device characterizations based on the experiments. The instrument is generally comprised of several high precision and sensitive Source and Measure Units (hereinafter “SMUs”). Each SMU can generally source and/or measure several magnitudes (voltage, current, etc.) at high precision with respect to sensitive parameters such as leakage current, crosstalk, electromagnetic interference, etc.

The DUT includes a plurality of nodes via which the magnitudes can be sourced and/or measured. To perform an experiment, the user connects each node of the DUT to a separate SMU. The instrument controls the SMUs, executing the experiment as defined by the user.

FIG. 1 schematically illustrates an “instrument” 100 including a plurality of SMU's 102, configured to perform an experiment to characterize a DUT 104.

A user may desire to characterize several DUTs at once to be efficient, for example, in case of failure of a specific DUT. In addition, the user may want to characterize several similar DUTs in order to accumulate statistical information. Conventionally, to characterize several DUTs at once, users connect several instruments in their setup, one instrument per DUT. For example, FIG. 2 schematically illustrates a configuration in which a plurality of instruments 202 are configured to each interact with a separate DUT 204. A host 206 is provided to interact with the various instruments 202.

### SUMMARY

An instrument is configured to coordinate execution of a plurality of experiments employing a plurality of source measurement units (SMU's) to characterize a plurality of devices under test (DUT's). Each experiment controller, of a plurality of experiment controllers, is configured to manage one of the plurality of experiments by, at least in part, controlling the SMU's allocated to that experiment. A main controller is configured to interoperate with a host to manage the experiment controllers.

For example, the instrument may be configured to provide experiment parameters to the SMU's prior to execution of the experiments. In one aspect, the main controller is configured to receive experiment parameters from a host controller external to the instrument. At least in part based on the received experiment parameters, the main controller configure which experiment controllers are to manage which experiment. The main controller is also configured to cause each experiment controller to provide appropriate ones of the received experiment parameters to the SMU's allocated to the experiment which that experiment controller is configured to manage.

In addition, for example, the main controller may be configured to adjust parameters of the experiments, by reconfiguring at least some of the experiment controllers, based on potential electrical interference between the experiments. The main controller may also be configured to receive information of the experiments from the experiment controllers with a priority maintained by the main controller.

In accordance with one aspect, at least some of the SMU's are configured to autonomously adjust execution of a portion of an experiment to which that SMU is allocated. For example, being configured to autonomously adjust execution of a portion of an experiment to which that SMU is allocated may include being configured to adjust execution speed parameters of that SMU.

### BRIEF DESCRIPTION OF THE DRAWINGS

FIG. 1 schematically illustrates an “instrument” including a plurality of SMU's, configured to perform an experiment to characterize a DUT.

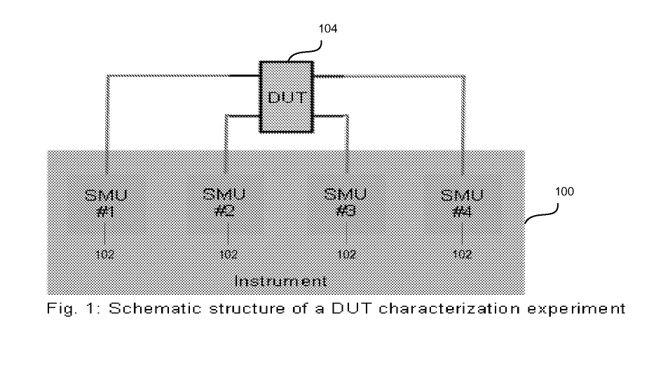

FIG. 2 schematically illustrates a configuration in which a plurality of instruments are configured to each interact with a separate DUT.

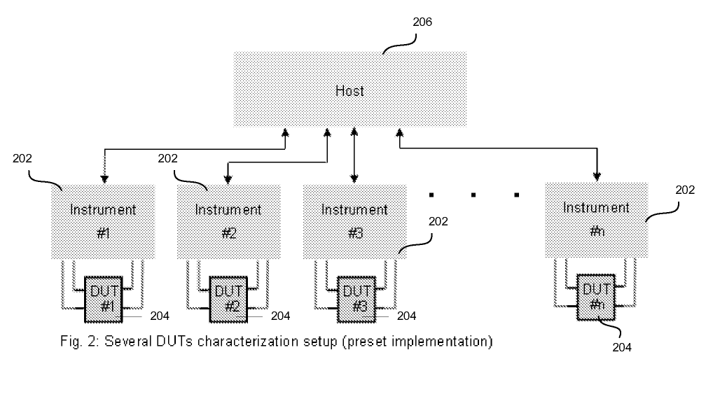

FIG. 3 schematically illustrates one example controller configuration.

FIG. 4 illustrates an example organization of modules of the FIG. 3 main controller.

FIG. 5 is a module flow diagram illustrating an example operational organization of the main controller.

FIG. 6 is a module flow diagram illustrating an example of operational organization of an experiment controller module and the interactions of the experiment controller modules with each other.

FIG. 7 is a flowchart illustrating an example of processing by an experiment controller module.

FIG. 8 illustrates an example of the SMU controller module organization.

FIG. 9 is a flow chart illustrating an example of processing by an SMU.

### DETAILED DESCRIPTION

The inventor has realized that it can be advantageous to coordinate the control of several experiments (for a particular DUT and for a plurality of DUT's) by coordinating the operation of the various SMU's. This may include advantageously combining control of a plurality of SMU's into a single instrument.

In order to shorten the time to run experiments, it has been proposed to configure the SMUs to operate faster. A potential problem with this approach is that it may be difficult to achieve the needed precision and satisfy all the sensitive parameters, while at the same time running faster. That is, speed of operation usually conflicts with accuracy. This implies that merely speeding up the experiments may not be an appropriate solution.

In one example, several experiments are executed simultaneously in the same instrument and under the same setup. The process of complete DUT characterization may include several long tasks, so running in parallel can save significant time. Examining the option of executing several experiments in parallel mode raises a concern, however: how can several experiments be run in parallel without causing interference among the tests?

For example, an SMU that executes as part of a sensitive experiment often sources and measures very low magnitudes, and therefore may lose precision if another SMU next to it operates as a high magnitude source. As a result, a variety of interference, such as electromagnetic interference, crosstalk and other may arise.

Thus, there is a desire for a controller that can operate in consideration of specific parameters and requirements of each experiment. This controller reacts substantially in real time to every event that happening in each of the experiments, in order to ensure that each experiment behaves substantially as expected and to minimize potential risk to the user (in case of hazardous phenomenon such as recognition of higher magnitudes then expected, interlock alarm, etc.). There are thus two apparent conflicting demands: on the one hand, the desire for a real time system that cause very fast source and exploration by each SMU; while on the other hand, as discussed earlier, fast execution is difficult to achieve and can even degrade precision and/or accuracy.

In accordance with an aspect, the controller is configured with a speed-balance feature. This feature is configured to control the speed of each SMU with respect to its parameters and all the other operating SMUs parameters in the instrument, taking into consideration the entire cross effect between SMUs that can arise due to the SMU operating speed. In addition to controlling speed, in some aspects, the controller is configured to avoid or minimize conflicts (“collisions”). Collisions may include, for example, when at least two SMUs try to communicate to a higher level at the same time or when a specific SMU is allocated more than once.

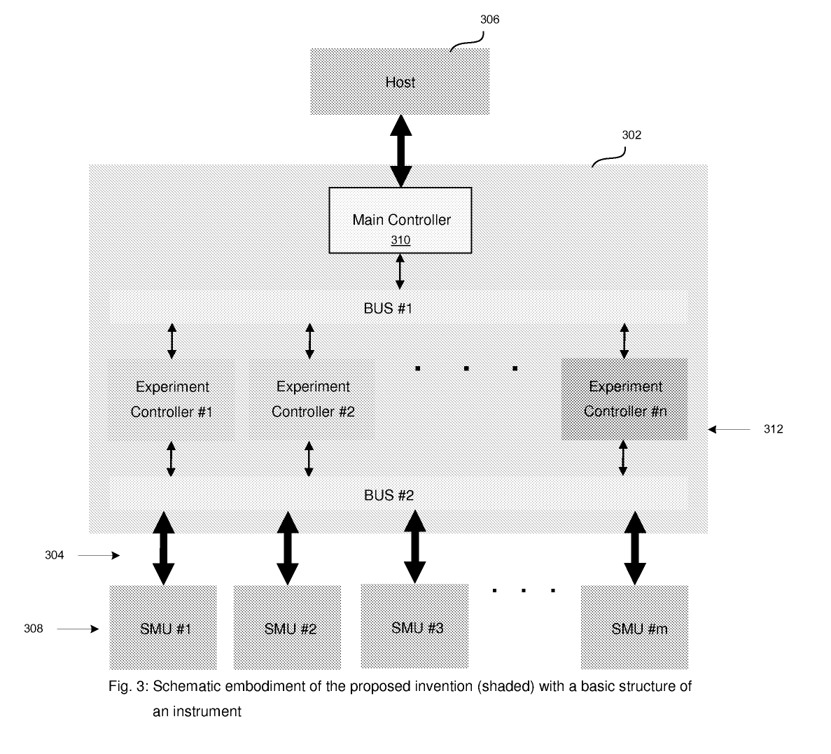

FIG. 3 schematically illustrates one example controller configuration. FIG. 3 shows the example controller 302 and its outputs/inputs 304. An instrument host 306 is configured to communicate with the controller 302, such that a selectable number of SMUs 308 may be controlled.

In the FIG. 3 example, the controller configuration is hierarchical. This structure is a practical implementation of a real time system, since tasks can work independently at lower levels without involving the higher levels. In the FIG. 3 example structure, there are two levels:
1. Main Controller 310 manages all the experiments, all other global data, and is responsible for priority delegation.
2. Experiment Controllers 312 each manages one experiment and controls the SMUs allocated to it by the main controller.

The structure hierarchical levels may be different from that shown in FIG. 3 for example, according to desired or required performance. For example, the SMUs can be active (3rd level) or passive.

In accordance with one method of operating the FIG. 3 example controller configuration, relevant experiment parameters are provided to the SMU's 308 prior to experiment execution. This method enables the experiment to run substantially without the SMU's 308 waiting for the instrument main controller 310. This can facilitate the main controller 310 being better able to support several experiments in parallel. In accordance with some examples, the main controller 310 receives the experiment's related parameters from the host 306, selects a suitable experiment controller 312 to control the experiment according to the parameters, and allocates the units selected by the user to this experiment.

Executing additional experiments in parallel with the currently running ones may result in “cross talk” between the experiments. For example, executing a high precision, low magnitude experiment can demand some unique environment conditions; a high voltage or current experiment operating next to it may affect the environment conditions. So operating an additional experiment in parallel with the currently running ones may inform some adaptations to some or all of the experiments (e.g., by updating executing parameters as necessary for running experiments). The main controller 310 can access (e.g. by holding it locally) saves all the information of all the experiments, and updates the configuration of each experiment controller to minimize interference between the experiments. The main controller 310 is configured to operate according to a smart algorithm that determines which parameters should be changed for each running experiment in order to run a new experiment without affecting all the rest.

It is advantageous for some events to be urgently reported to the main controller 310, to be quickly acted upon. The appropriate corresponding experiment controller 312 gets the priority to do so. However, if several such events happen at the same time, the main controller 310 can give the priority to the most hazardous event, before the others. For example, a set of priorities may be maintained by the main controller 310 in order to deal with such situations properly. This set of priorities can also help to minimize collisions between the experiments.

To minimize loss of accuracy due to high speed of SMU execution, each SMU may include its own controller configured to adjust the execution speed with respect to the SMU parameters (speed balance feature). Thus, for example, this feature may enable determination of a maximum executing speed for a particular SMU that will not affect (or will minimize effect on) precision and/or accuracy of that SMU. For example, consideration can be taken of the requirements of the currently running experiments. For example, the controller may run slower (relative to the experiment and main controllers) in order to minimize possible interference that would be caused by high frequencies.

To minimize crosstalk, electromagnetic interference, etc. between the SMUs and/or between the controllers, the communication networks used in this structure may generally facilitate noise-resistant-fast-data-bus, robustly operating in electromagnetically noisy environment.

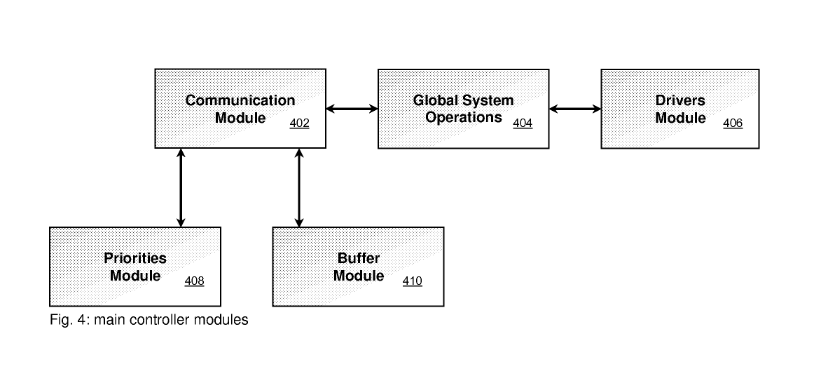

FIG. 4 illustrates an example organization of modules of the FIG. 3 main controller 310. The Communication Module 402 may be configured to act as a mediator between the host and other modules of the main controller. The Global System Operations module 404 may be configured to monitor and control the system fans, power supplies, interlock system identification, etc. using a Drivers Module 406 to communicate with the board peripheral devices. A Priorities Module 408 may be configured to operate on a list of priorities according to the experiment parameters and potential risk. The list may be maintained, for example, by the main controller, being updated as appropriate for smooth and safe operation. The Buffer Module 410 may be configured to hold the data received from all the experiments, e.g., until the host is ready to accept the data.

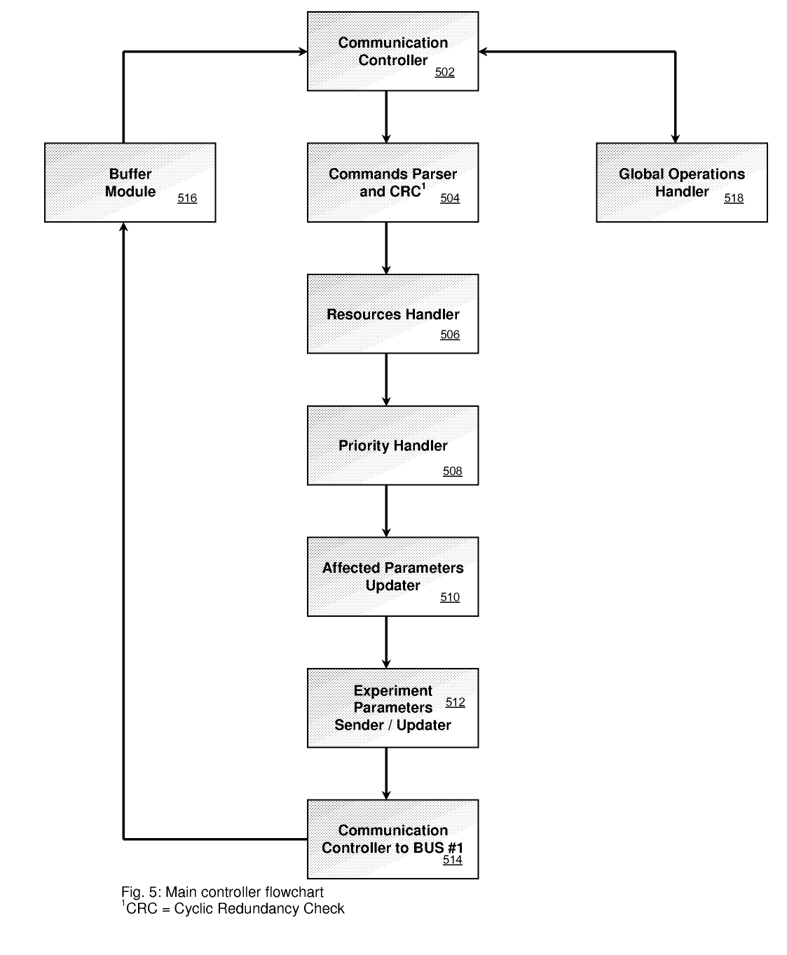

FIG. 5 is a module flow diagram illustrating an example operational organization of the main controller. Commands received by the Communication Controller 502 are parsed and checked for bit errors (by the Commands Parser and CRC 504). The Resources Handler 506 manages the resources (SMUs) status, minimizing chance of collision. The Priority Handler 508 updates a priorities list as appropriate according to each received command. The Affected Parameters Updater 510 determines which parameters (for every running experiment) to change according to the new command in order to effect smooth execution of command with minimal interference to the currently running experiments. The Experiment Parameter Sender/Updater 512, Communication Controller 514 and Buffer Module 516 are all involved in handling communication between the main controller and the experiment controllers over Bus #1. A Global Operations Handler 518 monitors and controls the system fans, power supplies, interlock system identification, etc.

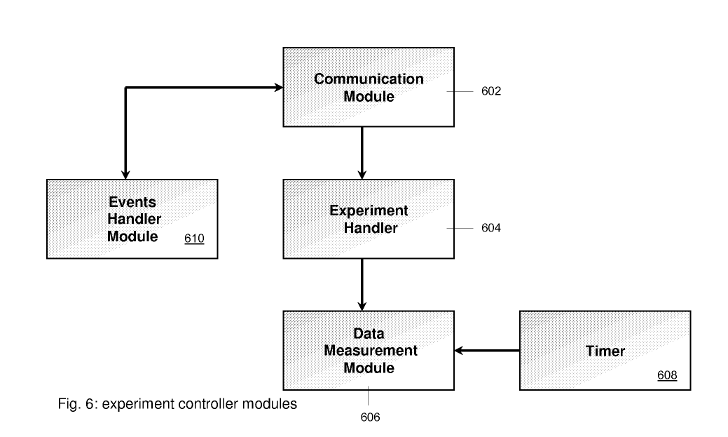

FIG. 6 is a module flow diagram illustrating an example of operational organization of an experiment controller module and the interactions of the experiment controller modules with each other. The Communication Module 602 is configured to act as a mediator between the main controller and buses #1 and #2. The Experiment Handler 604 is configured to cause execution of an experiment according to the user defined parameters that have been previously received from the main controller, managing the experiment by controlling the SMU's allocated to the experiment. The Data Measurement Module 606 is configured to sense all the data variables in the experiment (typically, in parallel) and add a time stamp (provided by the Timer Module 608) to any datum. The Events Handler Module 610 is configured to identify if an unexpected event (such as compliance, interlock, etc.) occurs and to handle the unexpected event as necessary.

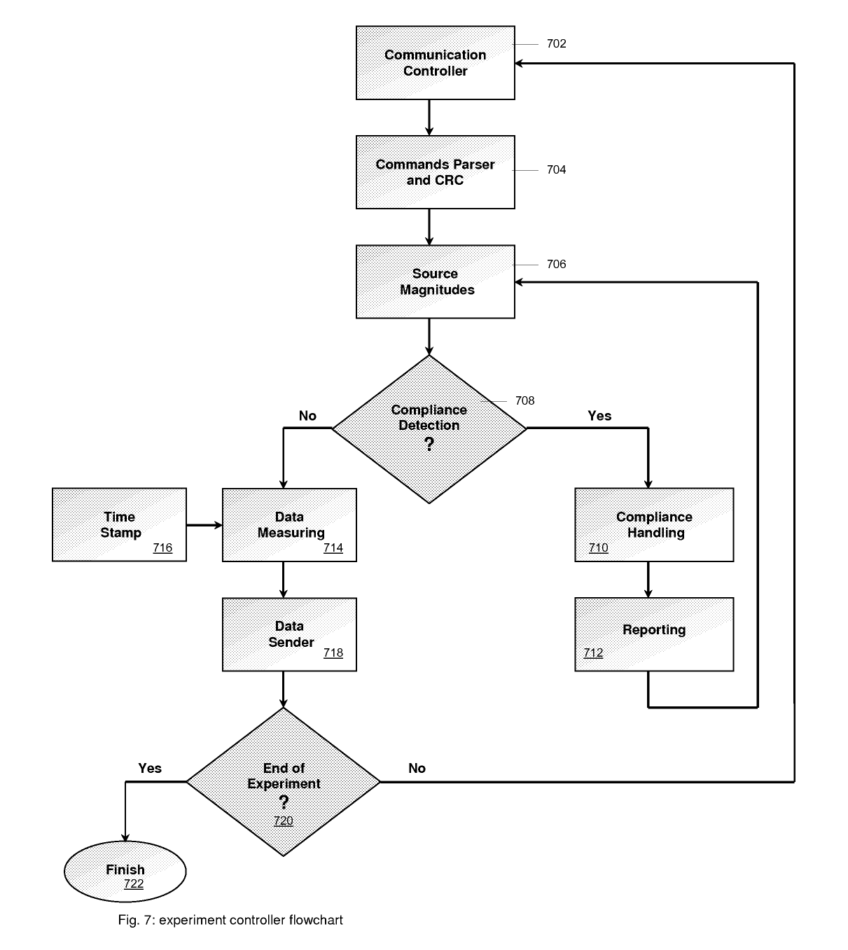

FIG. 7 is a flowchart illustrating an example of processing by an experiment controller module. The Communication Controller (702) and Commands Parser (704) operate to receive and process commands, such as described with reference to FIG. 6. After sourcing a next point magnitude to all the SMUs in the experiment (706), there is a check to determine if a compliance event happened (708). If so, the event is handled (710) and reported (712) as the user defined experiment may stop or continue, according to the user definitions. This loop continues until the last point defined in the experiment. If, according to the user defined conditions, the experiment continues (meaning that no unexpected event happened or the user defined conditions forces continuation), then data is measured (714), time stamped (716) and sent (718). It is determined at 720 if the experiment is over and, if so, the experiment processing is finished (722).

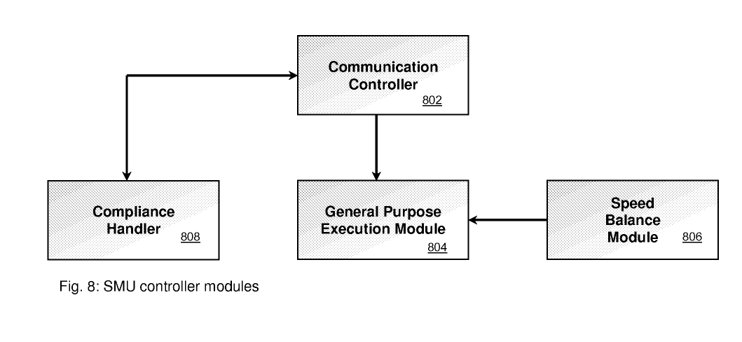

FIG. 8 illustrates an example of the SMU controller module organization. The Communication Controller 802 is configured to act as a mediator between the SMU controller and bus #2. The General Purpose Execution Module 804 is configured to operate the tasks according to the experiment controller request with respect to the SMU and experiment parameters, balancing (by Speed Balance Module 806) the execution speed in order to minimize possible lose of precision or cross affection (to other SMUs).

The Compliance Handler 808 senses the output magnitudes, compares each sensed value with the user defined compliance value and invokes a compliance event as appropriate.

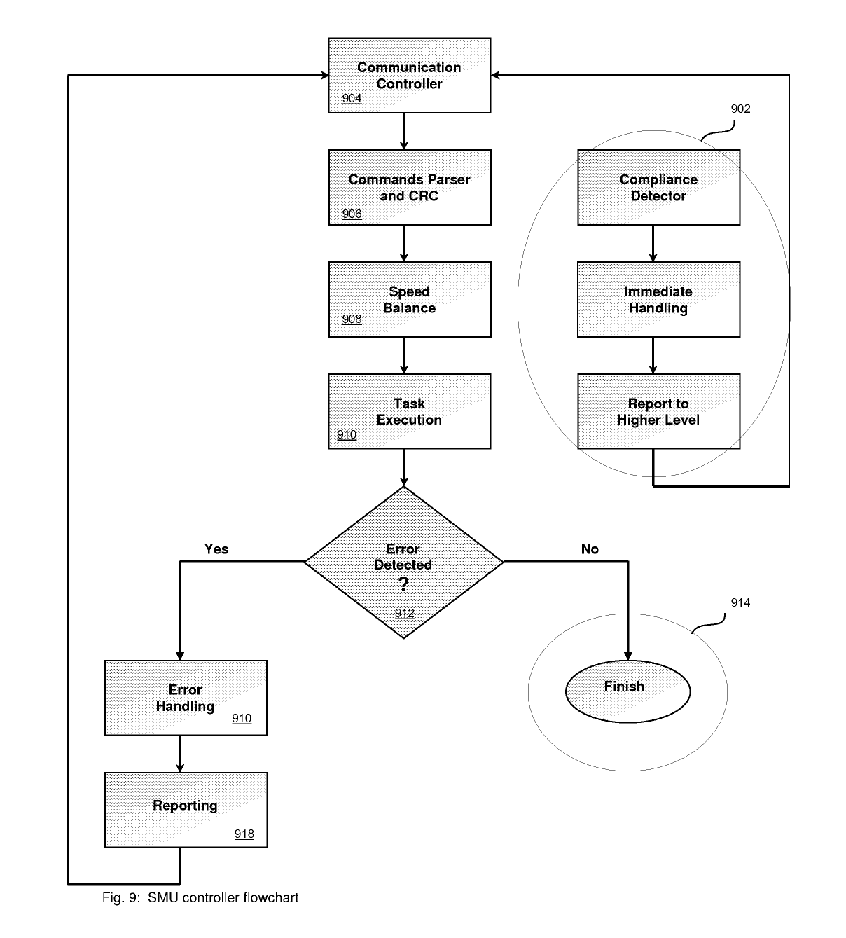

FIG. 9 is a flow chart illustrating an example of processing by an SMU. The SMU controller acts as slave to the experiment controller. Except compliance event reporting (902), this controller does not initiate any task. When a command is received by the communication controller (904), the received command(s) is parsed and error checked (906). The speed balance module sets an appropriate execution speed for the task (908) and the task is operated (910). When completed, based on whether an error is detected (912), the SMU controller returns the execution result (no errors 914 or error reporting 918).

We have thus described an approach to coordinating the control of several experiments (for a particular DUT and for a plurality of DUT's) by coordinating the operation of the various SMU's. As described, coordinating the control may include advantageously combining a plurality of SMU's into a single instrument and coordinating the control of the SMUs.

What is claimed is:

1. An instrument configured to coordinate execution of a plurality of experiments employing a plurality of source-measure units (SMU's) to characterize a plurality of devices under test (DUT's), the instrument comprising:
a plurality of experiment controllers, each experiment controller configured to manage one of the plurality of experiments by, at least in part, controlling the SMU's allocated to that experiment; and
a main controller configured to interoperate with a host to manage the experiment controllers.

2. The instrument of claim 1, wherein:
the instrument is configured to provide experiment parameters to the SMU's prior to execution of the experiments.

3. The instrument of claim 1, wherein the main controller is configured to:
receive experiment parameters from a host controller external to the instrument;
at least in part based on the received experiment parameters, configure which experiment controllers are to manage which experiment; and
cause each experiment controller to provide appropriate ones of the received experiment parameters to the SMU's allocated to the experiment which that experiment controller is configured to manage.

4. The instrument of claim 1, wherein:
the main controller is configured to adjust parameters of the experiments, by reconfiguring at least some of the experiment controllers, based on potential electrical interference between the experiments.

5. The instrument of claim 1, wherein:
the main controller is configured to receive information of the experiments from the experiment controllers with a priority maintained by the main controller.

6. The instrument of claim 1, further comprising:
the SMU's.

7. The instrument of claim 6, wherein:
at least some of the SMU's are configured to autonomously adjust execution of a portion of an experiment to which that SMU is allocated.

8. The instrument of claim 7, wherein:
being configured to autonomously adjust execution of a portion of an experiment to which that SMU is allocated includes being configured to adjust execution speed parameters of that SMU.

9. The instrument of claim 6, wherein:
the instrument is configured such that execution speed parameters of at least one of the SMU's are adjusted during execution of an experiment to which that SMU is allocated.
